(19) United States
(12) Patent Application Publication
(10) Pub. No.: US 2002/0121892 A1
(43) Pub. Date: Sep. 5, 2002

(54) Modulating device characterization method and apparatus

(75) Inventors: Gerd Vandersteen, Sint-Pieters-Leeuw (BE); Yves Rolain, Halle (BE); Alain Barel, Schaarbeek (BE)

Correspondence Address: KNOBBE MARTENS OLSON & BEAR LLP, 620 NEWPORT CENTER DRIVE, SIXTEENTH FLOOR, NEWPORT BEACH, CA, 92660, US

(73) Assignee: Interuniversitair Microelectronika Centrum (IMEC) Vrije Universiteit Brussel

(21) Appl. No.: 09/872,487

(22) Filed: May 31, 2001

Related U.S. Application Data
(60) Provisional application No. 60/208,446, filed on May 31, 2000.

(51) Int. Cl. G01R 19/18

(52) U.S. Cl. 324/118

(57) ABSTRACT

A method and apparatus to characterize a modulator without requiring access to modulator local oscillators. A periodic signal is input so that at least two tones are output, and the envelope of the filtered output is detected. The modulated output signal is generally differentially filtered before envelope detection, and the measured amplitude and phase of the envelope of the differentially filtered modulator output frequencies, combined with the known filter characteristics, are used to deduce the amplitude and phase of the modulated output. The modulator input signal frequencies may advantageously be controlled to substantially limit the output to frequencies which differ from a reference frequency by odd multiples of a delta frequency, reducing intermodulation components. In this special case the modulator output may be deduced from a squared envelope signal without a need for differential filtering. The deduced output, compared to the known input, characterizes the modulator at the input frequencies.

The present application claims the benefit under 35 USC §119(e) of copending provisional application No. 60/208,446, filed May 31, 2000.

### FIELD OF THE INVENTION

This invention relates to the field of electronic device performance analyzers, and more particularly to signal modulator analyzers.

### DESCRIPTION OF THE RELATED ART

Modulators are ubiquitous in wireless communications, and are used for the many frequency shifts employed in both transmission and reception of signals. A very high frequency communication system may utilize two or more frequency conversion modulators for each of the transmission path and the reception path. Frequency conversion modulators for shifting information signals both to and from baseband are generally incorporated within radio transceivers, i.e. a combined transmitter and receiver. A cellular telephone is a good example of a transceiver.

Modulators typically modulate one signal by multiplying it with a second signal. The first signal may be an information signal, and the second signal a carrier or frequency conversion signal. The carrier signal may be provided by a signal source which is external to the modulator, or by a local oscillator which is physically proximate to the modulator. The local oscillator signal is often not needed outside the immediate proximity of the modulator. Conveying the local oscillator signal away from the modulator generally requires special connections which at a minimum require extra manufacturing effort, and may cause undesirable interactions between the local oscillator signal and other signals in the transceiver. Therefore, it is desirable to avoid a need to convey the local oscillator signal away from the immediate proximity of the modulator. Such a modulator need only provide an information signal input and a modulated signal output.

Modern manufacturing techniques for complex devices like transceivers also require that the devices be testable. This is so that the various aspects of the manufacturing process can be monitored and, if necessary, corrected. It is therefore very useful to be able to characterize the performance of modulators, i.e. to determine and describe the output that a modulator will produce in response to particular inputs. Modulators are typically characterized by their frequency response, or the output frequency, amplitude and phase at one or more frequencies of the input. Several techniques are known for characterizing modulator performance by using analyzers, as explained below.

Spectrum Analyzer. This instrument measures the amplitude (magnitude) of the different spectral components present in a signal. By connecting (1) the modulator input signal, (2) the carrier (from the local oscillator), and (3) the modulated output signal to a spectrum analyzer, one can measure the amplitude relationship between each spectral component. Because the spectral analyzer measures only the amplitude of the spectral components, however, the measured frequency spectrum contains no information about the phase of the modulated output signal compared to the input signal.

Vector Signal Analyzer. In the appropriate setting, the sampler of a Hewlett Packard HP71500 Microwave Transition Analyzer (MTA) can be put in sub-sampling mode. In this mode of operation, the MTA generates a coherent frequency-down-shifted version of a high frequency modulated signal. Because this instrument can simultaneously digitize a low-frequency signal, such as the modulating signal, an amplitude and phase response can be obtained between the input and output frequency tones. This is only possible if the frequencies of the carrier and the modulation signal are phase coherent (Microwave Transition Analyzer. Product Note no 70820-2 and Lit no 5952-2543 September 1991, Hewlett-Packard). Thus, for this technique one needs full access to the carrier signal in order to synchronize it with the modulation signal and thereby make the two signals phase coherent.

Vector Network Analyzer. There are two techniques for performing a measurement of the response of a frequency-shifting device with a vector network analyzer.

In the first technique, the network analyzer is synchronized on one tone of the modulated signal to be measured by triggering the network analyzer on an identical tone generated by another mixing device (called the reference mixer). This is a reasonably accurate, but quite unusual operational mode of the network analyzer. The measurement is based on a comparison between the reference mixer output and the output of the mixer under test.

Users of this method, postulate that the reference mixer perform ideally and adds no phase shift between the tones of the modulation signal and the tones of the corresponding modulated signal. A drawback of this method resides in the fact that one has to postulate something that is not easy to verify (see M. Sipila, K. Lethinen, V. Porra, “High-Frequency Periodic Time-Domain Waveform Measurement System,” IEEE Trans. MTT, Vol. 36, No 10, October 1988, pp. 1397-1405, and Urs Lott “Measurement of Magnitude and Phase of Harmonics Generated in Nonlinear Microwave Two-Ports,” IEEE Trans. MTT, Vol. 37, No 10, October 1989, pp. 1506-1511).

In the second technique, the network analyzer is synchronized on a tone of the modulation signal. The mixer to be measured is then cascaded with an identical one in reverse position (i.e. the cascaded mixer performs frequency down-conversion if the mixer to be measured is performing frequency up-conversion, and vice versa). Both mixers are fed with the same carrier frequency. As such, the network analyzer measures the overall response of two identical mixers mounted in cascade. The response of one mixer is the square root of the overall measured response. An alternative of the same method consists of measuring different combinations of cascades obtained with three mixers and solving an appropriate set of equations.

A weak point of this last method is that the mixers must be able to work in forward and reverse mode and one has to postulate that the response is the same in both modes (see C. J. Clark, A. A. Moulthrop, M. S. Muha & C. P. Silva, “Transmission Response Measurements of Frequency-Translating Devices using a Vector Network Analyzer,” IEEE Trans. MTT, Vol. 44, No 12, December 1996, pp. 2724-2737).

Thus, the techniques which provide efficient and accurate characterization of modulator performance all require that the modulating signal be available to the analysis tools, which are of course external to the modulator. However, as explained previously, modulator manufacturing processes may be simplified by not bringing the local oscillator signal outside of the modulator. Accordingly, there is a need for a method and apparatus able to accurately and efficiently characterize the performance of a modulator without a need for access to the local oscillator signal.

### SUMMARY OF SOME INVENTIVE ASPECTS

To address the above-identified need, a method and apparatus is presented herein which enables efficient and accurate characterization of the performance of modulating devices without a need to access the local oscillator signal in a modulator. The method and apparatus may also be employed to determine the transfer characteristics for modulated signals when transferred through other devices, and whether or not the modulator local oscillator is available.

One inventive aspect is a method of characterizing a response of a modulating electronic device. A periodic signal having a plurality of frequency components is input to the device, and the envelope of a filtered version of the modulated output is obtained. Spectral components of the envelope of the filtered output signal are treated to deduce the modulator output for comparison to the input signal.

Another inventive aspect is an apparatus for characterizing a modulating electronic device response. The apparatus includes a signal generator which provides a periodic signal with a plurality of frequency components for a modulator under test, and an envelope detector which determines an envelope of a signal derived from an output of the modulator under test. A signal analyzer is included to determine characteristics of the envelope, as well as a calculator configured to determine modulator output phase and amplitude from the envelope.

If the modulator input signal is controlled so that the modulator output is primarily restricted to component frequencies differing from a reference frequency by odd multiples of a delta frequency, then the detected envelope of the modulator output, multiplied by itself (squared), may contain sufficient information to deduce the modulator output for those inputs. Otherwise, it may be necessary to split the modulator output signal, differentially filter the two identical output signals, and detect the envelope of each output signal. The modulator output can then be derived from the detected envelopes of the differentially filtered modulator output signals, in combination with the known filter characteristics. In any event, once the modulator output amplitude and phase is known, the modulator effect at the corresponding input frequencies is known.

### BRIEF DESCRIPTION OF THE DRAWINGS

FIG. 1 is a block representation of a modulator characterization measurement setup.

FIG. 2 is a block-diagram of a modulator which may be used with FIG. 1.

FIG. 3 is a system for characterizing signals which have been modulated.

FIG. 4 is an example, for a demodulator, of a measurement setup as shown in FIG. 1.

FIG. 5 graphically depicts successive operations for differential filtering and envelope detection of a multi-sine signal in accordance with one inventive method herein.

FIG. 6 schematically represents implementing differential filters by use of a delay line.

FIG. 7 is a measurement set-up used to validate some of the inventive aspects.

FIG. 8 is a graph comparing expected results with results using an inventive method.

FIG. 9 is a spectrum of an optimal input signal for some of the inventive aspects.

FIG. 10 is a spectrum of an envelope-detected modulator response to a FIG. 9 input.

FIG. 11 is a graph of family connections between even and odd spectrum frequencies.

FIG. 12 is a block diagram of a measurement setup for verifying some inventive aspects.

FIG. 13 is a graph comparing actual and expected results of a FIG. 12 measurement.

FIG. 14 is a flow chart of methods for characterizing modulated signals.

### DETAILED DESCRIPTION OF EMBODIMENTS OF CERTAIN INVENTIVE ASPECTS

General Measurement Setup

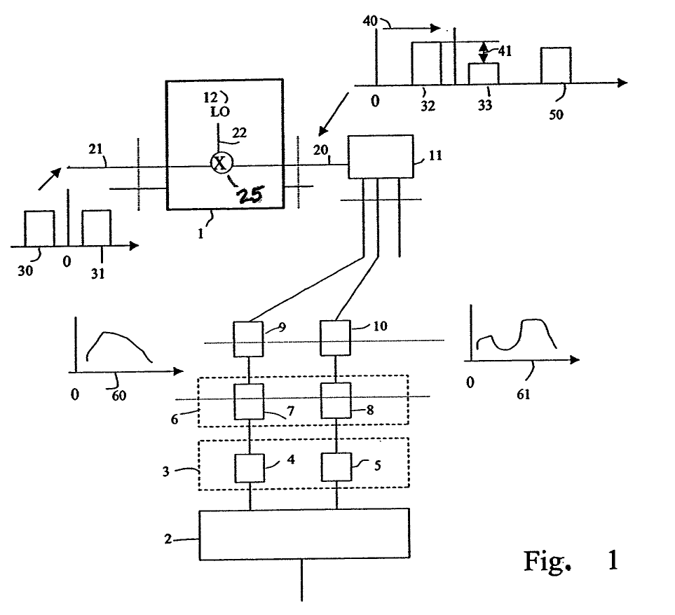

FIG. 1 shows a measurement setup for a modulating device 1. The modulating device 1 includes a local oscillator (LO) 12 which inputs a carrier signal 22 to a mixer 25. The carrier signal 22 may be produced internally, as shown, or input from an external device. A representative input 21 to the modulating device 1 is shown to consist of a periodic signal having equal sidebands 30 and 31 disposed about zero frequency. The modulating device 1 is assumed to affect the different frequency components differently, and to create new frequency components. Thus, an output, modulated signal 20, from the modulating device 1 is shown to contain components reflecting the input components 32 and 33, frequency shifted from zero by an amount 40. While the input sidebands 30 and 31 were equal, output sidebands 32 and 33 show a difference 41 in amplitude; this is a simplified representation of the general proposition that the mixer does not affect all input spectra the same. Indeed, the present method and apparatus is intended to characterize the variation in treatment of different spectral portions of the input signal by the modulating device 1, as represented for example by difference 41. The modulating device output 20 also includes additional frequency spectrum, represented by output signal component 50, resulting for example from intermodulation products.

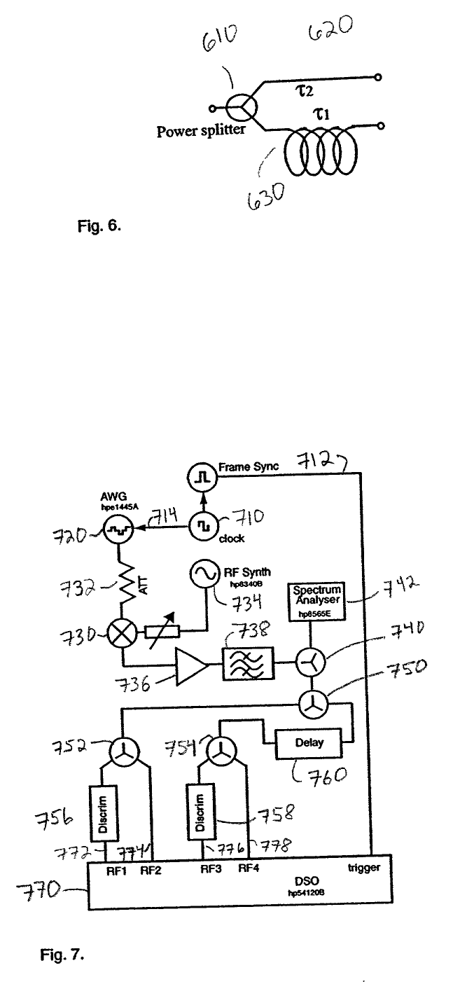

The output 20 from the modulating device 1 is applied to a signal splitter 11, which provides substantially identical copies of a signal derived from the output 20. One of these signal copies then enters a filter 9, and another enters a filter 10. The transfer function of these filters should be known, and should be different from each other over the spectrum of the incoming signal. A transfer function for the filter 9 is indicated by a graph 60; this is a known but arbitrary transfer function. A transfer function for the filter 10 is shown by a graph 61. The somewhat whimsical shape of the filters 9 and 10 transfer functions underscores that these transfer functions are different from each other, but otherwise arbitrary as long as they are known. The filters are preferably composed of analog devices. Referring for a moment to FIG. 6, an exemplary discriminating filter may be fed from a splitter 610, with one signal copy traveling through a transmission line 620 having a delay τ2, and the other signal copy traveling through a transmission line 630 (represented as an inductive element), having a longer delay τ1.

Both signals now enter an envelope detector block 6. The first filtered signal, from filter 9, is converted by a first envelope detector 7, while the second filtered signal, from filter 10, is converted by a second envelope detector 8. The properties of envelope detectors are well known in the art, and can be found in many reference book (see, for example, G. M. Miller, “Modern Electronic Communication,” Prentice Hall, 1993, pp. 140-142, L. Cohen, “Time-Frequency Analysis,” Prentice Hall, 1995, pp. 27-29, or M. Schwartz, “Information Transmission, Modulation, and Noise,” McGraw Hill, 1981, pp. 250-257). The effect of envelope detection is shown graphically in FIG. 5. Frequency domain graphs A-E, references 510-550, share the same range of frequencies centered on carrier frequency fc (the frequency of carrier component 514). Frequency domain graph A 510 shows an exemplary spectrum of a modulator output centered at carrier frequency 514, with lower sidebands 512 having an uncertain amplitude (and also phase) relationship to upper sidebands 516. Graph 520 represents a transfer function 522 for a discriminating filter which is applied to one of at least two substantially identical outputs (e.g. as represented by 510) from a signal splitter. Graph 530 indicates lower sideband components 532, carrier frequency component 534, and upper sideband components 536 of the signal represented by graph 510 after passing through the filter. Graph 540 shows, with arrow 558, the complex conjugates 552 of the lower sideband components being “folded” onto the upper sideband real frequency components 556. Finally, graph 560 shows the result at baseband of this operation, with the net real amplitudes of each frequency component comprising the product of these real and corresponding complex conjugate values.

The envelope detection in block 3 of FIG. 1 can be performed in different ways. A commonly used implementation employs Schottky diode rectifiers. Such diode detection completely ignores any coherence between modulation signals and the RF carriers, as long as the carrier frequency and the modulation bandwidth are sufficiently different. An amplitude response calibration of this type of circuit is useful to obtain accurate measurements. An alternative implementation of an envelope detector uses a Digital Sampling Oscilloscope (DSO) (see, for example, A. Barel and Y. Rolain, “A Microwave Multisine with Known Phase for the Calibration of Narrowbanded Nonlinear Vectorial Network Analyzer Measurements,” 1998, IEEE, MTT-S, Int. Microwave Symp. Digest, Vol. 3, pp. 1499-1502, Baltimore, June 1998; A. Barel and Y. Rolain, “Validation of a Microwave Multitone Signal with Known Phase,” 1999, IEEE, MTT-S, Int. Microwave Symp. Digest, Vol. 4, pp. 1659-1662, Anaheim, June 1999). When the RF carrier and the modulated signals are non-coherent, then an envelope detection may be performed by detecting either the RMS values or the peak values of a very large number (for example 4096) of acquisitions of the voltage at each relative sampled time point, referenced to a trigger point in the repetitive input signal 21.

Next, each signal is digitized and spectrally analyzed, for example by a digitizing analyzer 3 having at least two inputs, so that the first envelope-detected signal is digitized and analyzed by analyzer 4, and the second envelope-detected signal is digitized and analyzed by analyzer 5 within digitizing analyzer 3. The digitizers 4 and 5 are asynchronous to the carrier signal 22 within the modulating device 1, but are synchronously triggered by the modulating device input signal 21. The lack of synchronicity causes the sampled values to have a varying level due to the modulation by the carrier signal 22.

Digitized, envelope-detected signals which have been differently filtered may be obtained for input to calculation block 2 by alternative methods. For example, digitizing may be performed at the input of the envelope detectors 7 and 8, and envelope detection may be performed digitally, as would be done by a DSO (described above). In this event, spectral analysis will generally be performed digitally, since the information enters the analyzer in digital form. Also, a special case is described later in which the signal splitters and differential filters 9 and 10 may be omitted, and a single output from the modulating device 1 may be envelope-detected and digitized.

Modulated Signal Characterization

FIG. 3 shows a system for measuring amplitude and phase characteristics of signals which have been modulated. It does not require access to details of the modulation process, and may be used, for example, to characterize a modulator under test 320. A source 310 of modulation signals provides inputs 312 to the modulator 320. These inputs may include, for example, both I and Q inputs and one or more further modulation signals. In order to apply the system to measuring a modulator under test 320, information must be known about the input. If the modulator inputs are already known, then some, none or all of the modulation signals 312 may be conveyed to a digitizer 380, depending upon the level of confidence in the knowledge of the modulation signals. In FIG. 3, only one of the input signals is shown connected to the digitizer 380, primarily as a check on the signal and confirmation of triggering. All of the inputs could also be conveyed to the digitizer 380, particularly if the modulation input signal is not known with confidence. A synchronizing signal, such as the trigger 314, is generally used to provide a time reference between the input signals 312 and the output signal 330 for purposes of characterizing the phase relationship between these signals. The modulation signals 312 may comprise only one signal, or two (typically I & Q), or 3 as shown, or more. The modulator 320 combines the input modulation signals 312 in forming the modulated output signal 330.

The system shown in FIG. 3 need not be restricted to characterizing a modulator, but may determine amplitude and phase characteristics of any signals which have been modulated, irrespective of the applied modulation in most cases. In the more general case, a signal splitter module 340 is employed to create two copies of the modulated signal 330, and these two copies are differentially filtered through filter modules F1 350 and F2 360, which have different characteristics. The differently-filtered outputs enter an envelope detector module 370. In FIG. 3, the envelope detector module includes two analog device envelope detectors. However, envelope detection may be performed after digitization of the two differentially-filtered modulated signals, in which case the envelope detector module 370 would be a processing aspect within a digitizer block 380. Indeed, the digitizer block 380 includes both a digitizer module and also a processing module to perform the calculations needed to determine are discrete devices which output the envelope detected signals to a digitizer 380. The digitizer module within the digitizer block 380 is triggered from trigger signal 314, derived from the modulation clock. Typically, a number of traces will be taken by the digitizer 380, and some filtering applied to reduce measurement errors. If a large number of traces is taken, the envelope may be detected by filtered peak detection, and the envelope detector module 370 merged into the digitizer block 380, as explained above. Calculations, including those to determine the spectra of the signals entering the digitizer, may be performed in a computer, not shown, forming the processing module within the digitizer block 380. The calculations performed within the processing module are those explained in the section below subheaded “Calculation of Modulator Transfer Function.”

By determining the amplitude and phase characteristics of the modulated signal irrespective of the modulation, the system of FIG. 3 may be applied to characterize the modulator under test 320 by comparing the determined signal characteristics, which are on the output of the modulator, with the characteristics of the signal(s) 312 input to the modulator.

As explained further below, in a special case the system for characterizing the modulated signal irrespective of the modulation signal may omit filter modules 350 and 360, and splitter module 340. In this case, the system may be considered to include a modulation signal source module 310, which should be so adjusted as to cause the modulator 320 to produce output signals 330 to be substantially limited to components including a reference frequency and frequencies differing from the reference frequency by odd multiples of a delta frequency. In this special case, the envelope detector module 370 (which may be included within digitizer block 380 as a functional module) should be configured to determine the square of the detected envelope from the single signal 330. Though more signals may be used, in this special case the envelope detector module need only have one input. Thus, in this case the measurement system comprises the source module 310, an output signal 330 which has been modulated from the source signal and which is substantially restricted to spectral content having reference plus odd harmonic content, a squaring envelope detector module 370, and a digitizer module and processing module.

Demodulator Setup

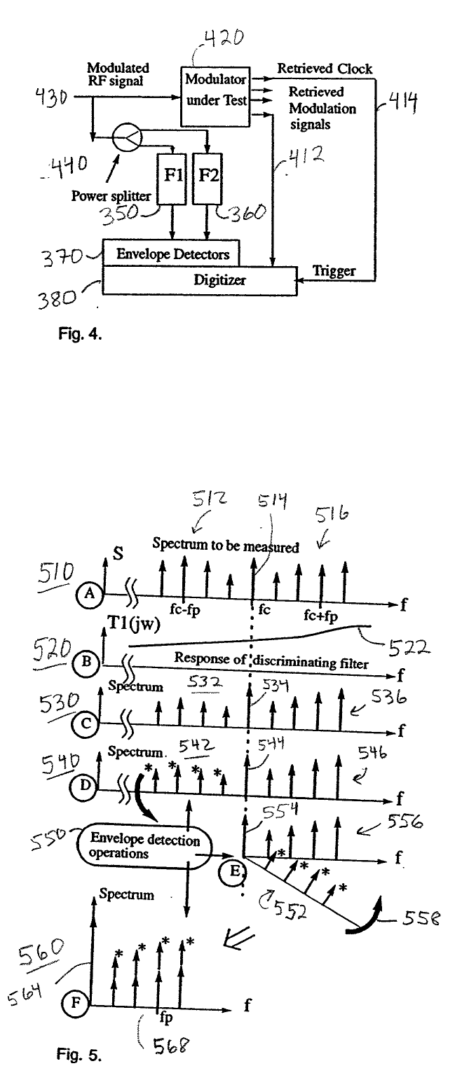

FIG. 4 shows special considerations for a demodulator under test. A demodulator receives a previously-modulated signal 430, which enters the demodulator 420 and also enters a splitter 440, which produces copies of the (previously) modulated input and delivers them to the differential filters F1 350 and F2 360. These similarly-referenced items may be substantially similar to the comparable F1, F2, envelope detectors and digitizer of FIG. 3, and accordingly the same reference numbers are used. A primary difference between the arrangement of FIG. 4 and that of FIG. 3 is that the output from the demodulator 420 are less likely to be known a priori, and thus are input into the digitizer 380. Also, in order to digitize the modulated and demodulated signal beginning at a reliable trigger point with respect to the unmodulated signal, a clock 414 is retrieved from the demodulator to trigger the digitizer.

Calculation of Modulated Signal Phase and Amplitude

With knowledge of the input signal 21, and of the filter functions (e.g. 60, 61), and of the resulting envelope-detected signal(s), the transfer function or characterization of the modulating device 1 may be determined by calculations in the calculation block 2. The nature of the calculations depends upon the nature of the input signal 21; the following procedure is applicable to a broad range of periodic modulator input signals, while another procedure is more efficient with a restricted range of inputs.

It will be recalled that the input signal 21 has a plurality of frequencies, minimal examples including the upper and lower sidebands of a periodic signal at baseband, or a pair of single sideband (SSB) signals. The inventive methods and apparatus described are applicable to the general case, in which different input frequencies each have arbitrary phase and amplitude with respect to other input frequencies. Each frequency input fₚ produces a pair of tones when frequency shifted by f_{c}. For each pair of tones (spectral terms at f_{c}−fₚ and f_{c}+fₚ), the measured signal in the envelope at the corresponding baseband frequency fₚ, namely a(fₚ), is essentially the sum of two terms. The first is the complex conjugate of the product of the lower sideband output tone, measured as s(f_{c}−fₚ), multiplied by the response T(f_{c}−fₚ) of the weighting filter at the frequency f_{c} fₚ, and the second is the product of the upper sideband output tone s(f_{c}+fₚ) multiplied by the response T(f_{c}+fₚ) of the differential (weighting) filter at the frequency f_{c}+fₚ:

a(fₚ)=conj{[T(f_{c}−fₚ)·s(f_{c}−fₚ)]}+(T(f_{c}+fₚ)·s(f_{c}+fₚ)) (1)

It can be seen that the measured amplitude and phase of a term present in the envelope gives only a mix-up of information about the corresponding lower- and upper-sideband terms in the modulated RF signal output. Some more effort is required to determine the original spectral tones s(f_{c}−fₚ) and s(f_{c}+fₚ).

Writing the above equation (1) for both paths of the split signal generates a system of two equations with two unknowns, s(f_{c}−fₚ) and s(f_{c}+fₚ), which can be solved provided the determinant

$$\vert \begin{matrix}conj [ T 1 ( {f}_{c} - {f}_{p} ) ] & T 1 ( {f}_{c} + {f}_{p} ) \\ conj [ T 2 ( {f}_{c} - {f}_{p} ) ] & T 2 ( {f}_{c} + {f}_{p} )\end{matrix} \vert \qquad ( 2 )$$

is different than zero. This condition establishes the benefit of the two filters F1 and F2 having different responses T1≠T2. Since they differently affect the split, and thus substantially identical, versions of the modulator output, these two filters may be referred to as “differential” filters. The requirement T1≠T2 can be fulfilled by a large choice of filters. A simple example of such filters consists of a pair of delay lines such that sin[ω_{c}(τ₁−τ₂)] differs from zero, where τ₁ and τ₂ are the respective delays of the two lines. This is equivalent to say that the difference of length of the two delay lines τ₁−τ₂ may not be equal to half a wavelength at the carrier frequency. Such differential delay filters may be implemented by different lengths of transmission line (e.g. coax cables). Another example is a low (or high)-pass filter affecting the frequencies of interest; the other filter, again, may be a straight wire. Note that more than two different filters may be used if the signal is split into more copies, providing an option of basing the calculations on different combinations of filtered outputs.

The skilled person will generally determine the upper and lower sidebands resulting from a first frequency of the periodic input signal, fₚ, without need for direct reference to the local oscillator within the modulating device 1. The spectral value at these frequencies from the two envelope-detected differentially filtered output signals, after digitizing and spectral analysis, are a1(fₚ) and a2(fₚ). For al(fₚ), T in equation (1) is T1, while T is T2 for a2(fₚ). Thus, one determines the characterization of the modulating device for fₚ, s(f_{c}−fₚ) and s(f_{c}+fₚ), using

$$[ \begin{matrix}conj ( s ( {f}_{c} - {f}_{p} ) ) \\ s ( {f}_{c} + {f}_{p} )\end{matrix} ] = {[ \begin{matrix}conj [ T 1 ( {f}_{c} - {f}_{p} ) ] & T 1 ( {f}_{c} + {f}_{p} ) \\ conj [ T 2 ( {f}_{c} - {f}_{p} ) ] & T 2 ( {f}_{c} + {f}_{p} )\end{matrix} ]}^{- 1} [ \begin{matrix}a 1 ( {f}_{p} ) \\ a 2 ( {f}_{p} )\end{matrix} ]$$

This calculation determines the complex spectra of the modulating device output, and hence determines both gain and phase information of the output spectrum.

The calculation method for the pair of tones s(f_{c}−fₚ) and s(f_{c}+fₚ) must be repeated for each pair of tones present in the RF signal, corresponding to each spectral frequency component in the input signal 21. Particularly when there are many frequencies in the input signal, special care should be taken to avoid the superposition of unwanted intermodulation terms on the wanted terms in the envelope signal. These intermodulation terms may be reduced by avoiding even spectral components (in the frequency domain. In the absence of any such even spectral components in the input signal, the measurements of the odd spectral components will not be disturbed by even order nonlinear distortions.

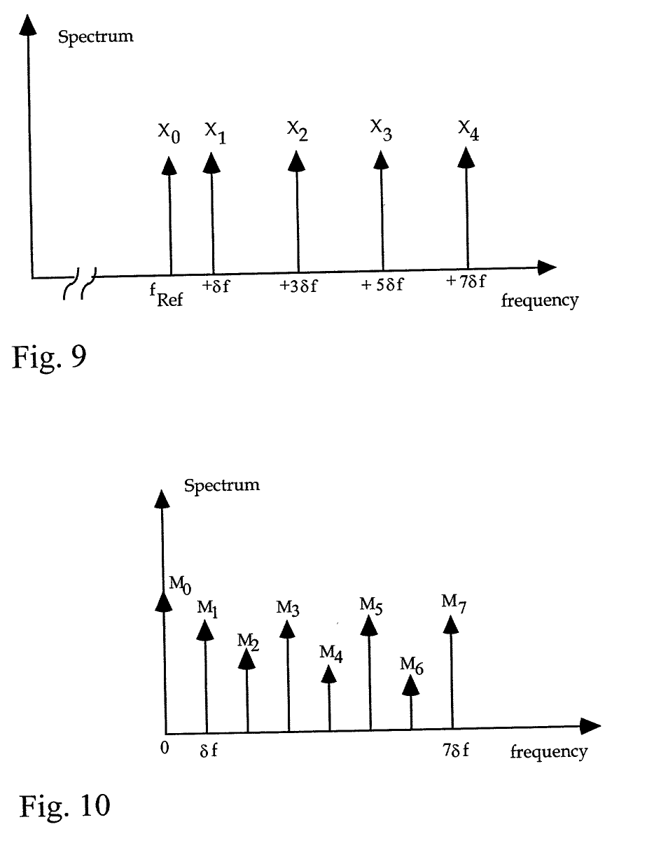

An example of an odd output spectrum of the modulator is represented in FIG. 9. Such output spectrum can be obtained through the selection of the I and Q signals at the input of the modulator. This can be done using, for example, a SSB modulation of a baseband signal with an odd multisine. A group signal g(t) of multiple sinusoidal frequencies can be represented as

$$g ( t ) = {\sum }_{p = 0}^{n} {a}_{p} cos ( 2 π {f}_{p} t + {ϕ}_{p} )$$

In FIG. 9, each of the frequencies is either a reference frequency X₀, or a sum of X₀ plus an odd multiple of a frequency differential δf. Thus, X₁ to X₄ are fRef, fRef+δf, fRef+3δf, fRef+5δf, and fRef+7δf, respectively. Any amplitude and relative phase may be used for these input components. Such an input, then, though having any number of frequencies, is desirable to reduce intermodulation disturbances to the measurement and makes it possible to relax the constraint on the filters T1 and T2 as will be explained below.

To develop the envelope of the signal, g(t) is rewritten as exponentials, so that the terms on the positive frequency axis and those situated on the negative frequency axis appear separately:

$$g ( t ) = {\sum }_{p = 0}^{n} \frac{{a}_{p}}{2} exp [ - j ( 2 π {f}_{p} t + {ϕ}_{p} ) ] + {\sum }_{p = 0}^{n} \frac{{a}_{p}}{2} exp [ + j ( 2 π {f}_{p} t + {ϕ}_{p} ) or \\ g ( t ) = {\sum }_{p = 0}^{n} \frac{{a}_{p}}{2} exp ( - j {ϕ}_{p} ) exp ( - j2π {f}_{p} t ) + {\sum }_{p = 0}^{n} \frac{{a}_{p}}{2} exp ( + j {ϕ}_{p} ) exp ( + j2π {f}_{p} t ) \\ or finally \\ g ( t ) = {\sum }_{p = 0}^{n} \frac{{X}_{p}^{*}}{2} exp ( - j2π {f}_{p} t ) + {\sum }_{p = 0}^{n} \frac{{X}_{p}}{2} exp ( + j2π {f}_{p} t )$$

where X*ₚ stands for the complex conjugate of the phasor Xₚ.

This leads to the Spectrum G of the multisine group signal:

$$G ( f ) = {\sum }_{p = 0}^{n} \frac{{X}_{p}^{*}}{2} δ ( f + {f}_{p} ) + {\sum }_{p = 0}^{n} \frac{{X}_{p}}{2} δ ( f - {f}_{p} )$$

The envelope of the signal g(t) is thus given by the following time and spectral expressions:

a(t)=g(t)+jg*(t)

A(f)=G(f)+jG*(f)

or for the multisine:

$$A ( f ) = {\sum }_{p = 0}^{n} {X}_{p} δ ( f - {f}_{p}$$

In fact, the square of the envelope is used:

|a(t)|²=a(t).a*(t)

|A(f)|²=A(f)\mathring{x}Ã(f)

$${A}^{2} ( f ) = {\sum }_{p} {\sum }_{q} {X}_{p} {X}_{q}^{*} δ ( f - {f}_{p} + {f}_{q} )$$

This shows clearly that the envelope operator (the square of the envelope) performs a frequency down conversion of the signal. Indeed, all spectral contributions consist of products of two terms: one term chosen in the positive frequency axis while the other is chosen in the positive frequency axis of the original spectrum of g(t).

Because the envelope operator (square of the envelope) generates only spectral terms situated at frequencies equal to the difference of the frequency of the RF terms, the RF signal is downconverted to baseband. FIG. 10 shows the result of the envelope operator applied to a modulated output, optimum envelope detector input signal as shown in FIG. 9. In FIG. 10, the expressions Mᵢ are the measured spectral components of the squared envelope signal at frequency i. It is apparent that only multiples of δf are present. The table below gives all of the generated mixing terms:

| | | | | |
|---|---|---|---|---|
| X₀X₀* | X₁X₀* | X₂X₀* | X₃X₀* | X₄X₀* |
| X₀X₁* | X₁X₁* | X₂X₁* | X₃X₁* | X₄X₁* |
| X₀X₂* | X₁X₂* | X₂X₂* | X₃X₂* | X₄X₂* |
| X₀X₃* | X₁X₃* | X₂X₃* | X₃X₃* | X₄X₃* |
| X₀X₄* | X₁X₄* | X₂X₄* | X₃X₄* | X₄X₄* |

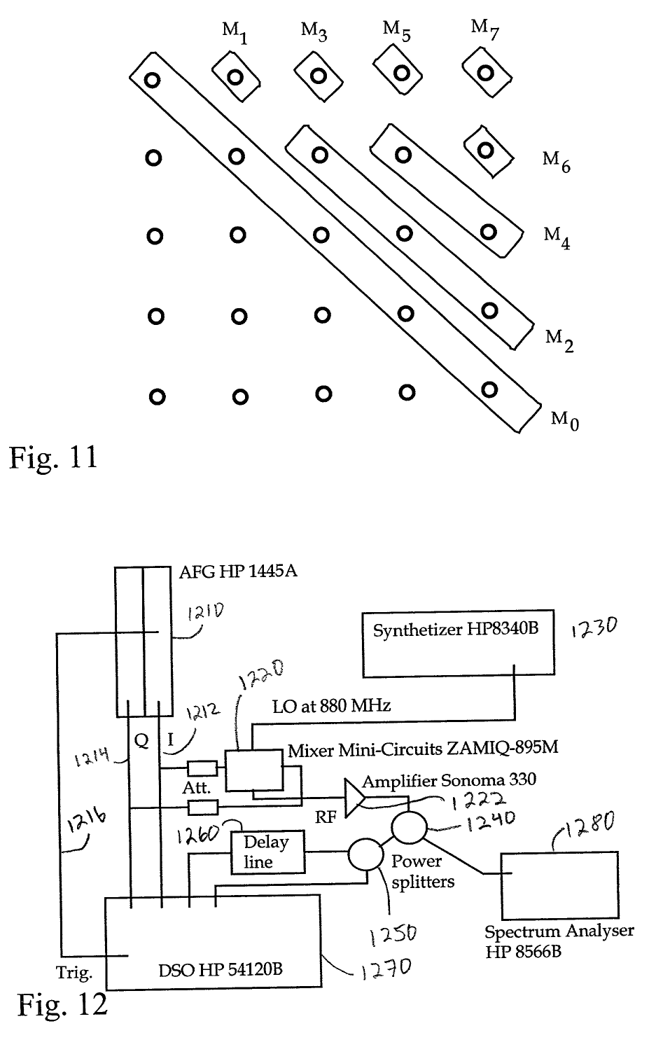

The frequencies of these terms are readily located. FIG. 11 represents the above list of mixing terms with a matrix of placeholder circles, and shows graphically how the contributions from each of the different mixing terms are grouped. The measured component at a particular frequency (in this example, M₀ to M₇) is the sum of the different contributions in the group associated with the particular frequency component. For example, M₀, the DC value as can be seen in FIG. 10, is associated with a group on a diagonal of all mixing terms which have the same frequency real and complex conjugate terms, and which accordingly all appear at baseband at the frequency which is the difference of the real and complex conjugate frequencies, in this case 0 Hz. All the components in this diagonal group are therefore added up and contribute to the DC value (M₀).

Note the singletons at the top row of this representation, indicating that these contributions can be determined directly out of the measured spectra of Mi. The combinations graphically shown in FIG. 11 are described analytically below.

There are two families of spectral terms in the square of the envelope signal. The first family consists of the odd frequency terms M₁, M₃, M₅ and M₇, which are produced by systematically mixing the reference term X₀ with X₁, X₂, X₃ and X₄:

M₁=2X₁X*₀ M₅=2X₃X*₀

M₃=2X₂X*₀ M₇=2X₄X*₀

The second family consists of the even frequency terms M₂, M₄ and M₆, which are produced by mutually mixing the terms X1, X2, X3 and X4:

M₂=X₂X*₁+X₃X*₂+X₄X*₃

M₄=X₃X*₁+X₄X*₂

M₆=X₄X*₁

The term at DC is given by the expression:

M₀=X₀X*₀+X₁X*₁+X₂X*₂+X₃X*₃+X₄X*₄

The unknown spectral lines are now expressed as ratios to the reference term X₀:

X₀=1X₀

X₁=x₁X₀ X₃=x₃X₀

X₂=x₂X₀ X₄=x₄X₀

where the new unknowns are the relative phasors: x₁, x₂, x₃ and x₄.

Replacing into the odd measured frequencies yields:

M₁=2x₁|X₀|² M₅=2x₃|X₀|²

M₃=2x₂|X₀|² M₇=2x₄|X₀|²

Inversion of these equations yield the relative unknown phasors x₁, x₂, x₃ and x₄.

$${x}_{1} = \frac{{M}_{1}}{2 {\vert {X}_{0} \vert}^{2}} {x}_{3} = \frac{{M}_{5}}{2 {\vert {X}_{0} \vert}^{2}}$$

$${x}_{2} = \frac{{M}_{3}}{2 {\vert {X}_{0} \vert}^{2}} {x}_{4} = \frac{{M}_{7}}{2 {\vert {X}_{0} \vert}^{2}}$$

X₀ still remains unknown but it will be solved in the next two steps.

Introducing the relative spectra into all the even measured frequencies gives (including the DC term):

M₀=(1+x₁x*₁+x₂x*₂+x₃x*₃+x₄x*₄)|X₀|²

M₂=(x₂x*₁+x₃x*₂+x₄x*₃)|X₀|²

M₄=(x₃x*₁+x₄x*₂)|X₀|²

M₆=(x₄x*₁)|X₀|²

Further replacing the value of the relative phasors by their respective relation with the measured data gives:

M₀=(4|X₀⁴+|M₁|²+|M₃|²+|M₅|²+M₇|²)/4|X₀|²

M₂=(M₃M*₁+M₅M*₃+M₇M*₅)/4|X₀|²

M₄=(M₅M*₁+M₇M*₃)/4|X₀|²

M₆=(M₇M*₁)/4|X₀|²

Each of the three last equations permits independent determination of the amplitude of the reference term X₀:

$$\vert {X}_{0} \vert = \sqrt{\frac{{M}_{3} {M}_{1}^{*} + {M}_{5} {M}_{3}^{*} + {M}_{7} {M}_{5}^{*}}{2 {M}_{2}}}$$

$$\vert {X}_{0} \vert = \sqrt{\frac{{M}_{5} {M}_{1}^{*} + {M}_{7} {M}_{3}^{*}}{2 {M}_{4}}}$$

$$\vert {X}_{0} \vert = \sqrt{\frac{{M}_{7} {M}_{1}^{*}}{2 {M}_{6}}}$$

The similarity of the three estimated values of |X₀| gives an assessment of the quality the measurement method. The equation involving the measurement at DC can be used as a complementary check-sum. Since the reference tone X₀ is arbitrary, its phase is not needed and need not be determined. Once that the norm of X₀ is determined and a phase has been chosen, e.g. a phase equal to zero, then one can compute the spectral components Xᵢ immediately out of the complex measured values Mᵢ.

As will be observed, the foregoing results do not require the use of differential filters to distinguish the contribution of the modulator to the signals. The envelope of the output signal, which in the more general case must be combined with the envelope of a differently filtered version of the output signal, at least in this case can simply be combined with itself as a squared envelope operation. This simplified operation is sufficient due to the specially designed spectral content of the output signal.

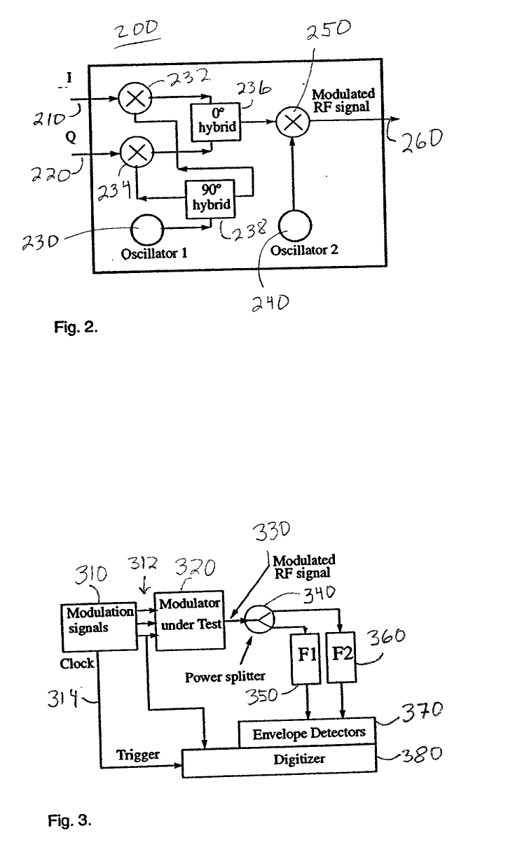

A typical quadrature modulator, common in modem communications systems, is shown in FIG. 2. Incoming signals I (210) and Q (220) are mixed in mixers 232 and 234 with the output of a quadrature oscillator 230 via a splitter 238, and these signals further combined in combiner 236, to put the signals 90 degrees out of phase with each other. The mixed signal is then modulated in mixer 250 with an output from Oscillator 2 (240) to produce the modulated output 260.

The device under test is an IQ modulator. The output signal of such an IQ modulator can be described as I(t) cos (fc t)+Q(t) sin (fc t) where fc represents the carrier frequency, t the time instance and I(t) and Q(t) the I and the Q signals as a function of the time. If control over both the I and the Q signal is available, then it is possible to generate an arbitrary modulated spectrum. If full control is not available, such as in single-input system (when Q(t) is always equal to zero), controlling the output spectrum is much more difficult.

Even having access to both I and Q inputs, and using a quadrature modulator, it is not a completely mechanical process to provide input signals such that the output follows the form shown in FIG. 9, i.e. having spectral components (f0, f0+df, f0+3df, . . . f0+(2k+1)df). Different signals for I(t) and Q(t) can be proposed for obtaining this result. The simplest solution that can be readily described is the use of standard SSB (single sideband) modulation, where the Q(t) input is a version of I(t) which has been filtered using a Hilbert transform. The Hilbert transform of a signal is given by the following operation in the frequency domain:

\tilde{S}(f)=[−jsgn(f)]S(f)

which gives for the multisine:

$$S ( f ) = - j [ - {\sum }_{p = 0}^{n} \frac{{X}_{p}^{*}}{2} δ ( f + {f}_{p} ) + {\sum }_{p = 0}^{n} \frac{{X}_{p}}{2} δ ( f - {f}_{p} ) ]$$

A basic explanation of such an SSB can be found in the first chapter of “The Communications Handbook,” Jerry D. Gibson, Editor-in-Chief, CRC press & IEEE press, 1997. If a SSB modulation is used, then f0 will represent the carrier fc (hence, the SSB modulation does not uses a suppressed carrier, but introduces a small carrier using DC component of the I(t) signal). The other signals, f0+df, f0+3df, . . . f0+(2k+1)df are generated by using an odd multisine for the I(t) signal. This means that I(t) has a power spectrum in which only the odd frequency components are excited (df, 3df, 5df, . . . (2k+1)df).

Having produced an output signal from the modulator having characteristics substantially similar to those shown in FIG. 9, the method described above employing the envelope operator (square of the detected envelope) may be employed to characterize the transfer function of the modulator, without a need for splitting and differentially filtering the modulator output signals. Such a modulator input signal is also useful for characterization using the differentially filtered output signals, because it limits the intermodulation products produced by the modulator which could otherwise confuse the characterization calculations.

Verification Testing of Sideband Signals on Carrier

FIG. 7 shows a test setup used for verification of some of the inventive aspects. A separate clock source 710 synchronizes a trigger to a signal generator 720 and to the trigger input of a digital sampling oscilloscope (DSO) 720, in this case a Hewlett Packard hp54120B. The signal generator 720 provides a “modulator input” signal through attenuator 732 to discrete mixer 730. The modulator input signal from generator 720 is known, and thus is not entered into a DSO 770. The mixer 730 mixes the modulator input signal with a carrier signal generated by a carrier synthesizer 734 (Hewlett Packard hp6340B), which acts as the local oscillator. Note that the output from the synthesizer 734 is not input to any measurement device, and also is not triggered, and thus is asymmetric with respect to the rest of the circuit. The output from the mixer 730 is buffered by buffer 736, and then filtered by bandpass filter 738. At this point the signal would ordinarily proceed directly to a splitter 750, but for test purposes is first split by splitter 740 to provide a copy of the signal for analysis by a spectrum analyzer 742 (a Hewlett Packard hp 8565E). The other signal proceeds to the splitter 750. One output proceeds to an input 774 of a DSO (Hewlett Packard hp54120B) by way of another splitter 752. The other output from the splitter 750 proceeds through differential delay line 760 to another input 778 of the DSO 770, by way of yet another splitter 754. The splitters 752 and 754, along with their associated delay circuits 756 and 758 (each 129.5 pS) are used to determine the signal amplitude and phase which is output from the splitter 750 either directly (as tested using splitter 752 and discriminating filter 756), or after the known delay 760 (as tested using splitter 754 and discriminating filter 758). Thus, the validation setup does not explicitly test the performance of the modulator represented by the mixer 730, buffer 736 and bandpass filter 738, but instead examines the same modulated signal and determines the amplitude and phase characteristics for the delayed and undelayed outputs of the splitter 750. The known delay 760 (73 nS) should provide a flat amplitude response, and a linearly changing phase, so that the two determined signals differ only by phase. Accordingly, if the measurements and calculations lead to this expected characteristic then both the amplitude and phase characteristics of an output signal have been determined accurately, verifying the technique.

The DSO inputs are sampled simultaneously, asynchronously to the carrier from the synthesizer 734. A large number (e.g. 4096) of traces of the input signal are taken, and the statistical peak reading (using a standard deviation) of the traces at each time point relative to the frame sync signal 712 is maintained as the envelope of the signal; thus, this is an example of a digital envelope detection system. The superposed folded tones are extracted from the envelope by use of a Fourier transformation (FFT). These tones are then multiplied by the inverse of the matrix T, as explained previously, to retrieve the original amplitude and phase of the sideband tones.

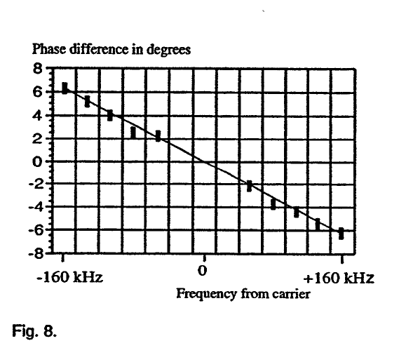

FIG. 8 shows the phase difference between the sideband tones obtained with the validation measurement setup, compared to the expected value due to the known delay line 760. The measured and calculated results differ from the expected phase value by less than a degree, which is close to the deviation observed using a well-known carrier frequency shuffling method (A. Barel and Y. Rolain, “Validation of a Microwave Multitone Signal with Known Phase,” 1999 IEEE MTT-S Int. Microwave Symp. Digest, Vol. 4, pp. 1659-1662, Anaheim, June '99).

Verification Testing of Restricted Odd Harmonic Modulated Signals

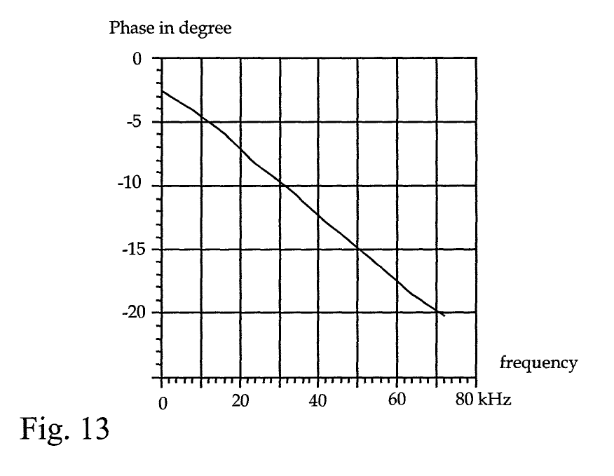

As explained above, measurement of transfer functions of a modulating device may be simplified by controlling I and Q inputs to a quadrature modulator so as to produce a restricted set of modulated output components, as shown in FIG. 9. The test setup is shown in FIG. 12. As in the testing of FIG. 7, the mixer transfer function itself is not examined, because it has an uncertain value. Rather, the signal produced by the mixer is split, one side delayed by a known delay, and the results examined according to the calculations described above to determine the character of the modulated signal with and without the known delay. A ten-frequency multitone signal at harmonics of 40 kHz is disposed above a reference frequency (carrier signal) of 20 kHz.

In FIG. 12, a signal generator 1210 produces modulation signals I (1212) and Q (1214). A quadrature mixer 1220 mixes the modulation signals with a local oscillator signal from a synthesizer 1230, buffers the output with amplifier 1222, and splits the signal with splitter 1240. This splitter simply permits a spectrum analyzer 1280 to examine the signal. Virtually identical copies of the mixed signal are provided by splitter 1250; one of these is delayed by known delay line 1260, while the other is not delayed. These delayed and undelayed versions of the modulator output signal are examined directly by a DSO 1270. Note that each signal is analyzed without using a further splitter and delay line (e.g. 752 and 756 of FIG. 7) as is used by the more general technique. However, as with FIG. 7, each signal is sampled numerous times, triggered on the trigger output 1216 from the modulation signal generator 1210, and the envelope is determined by statistical analysis of the sampled data, performed via software programs. The sampling of the DSO 1270 is again asynchronous to the local oscillator 1230. The delay 1260 is again 73 nS. FIG. 13 shows the difference between the signal characteristics of the delayed and undelayed output from the splitter 1250, as calculated by the squared-envelope method. The experimental results indicate that the output amplitudes are substantially identical, and the phase of the two signals differ by an amount corresponding to the expected delay of 73 nS.

Modulated Signal Characteristic Measurement Methods

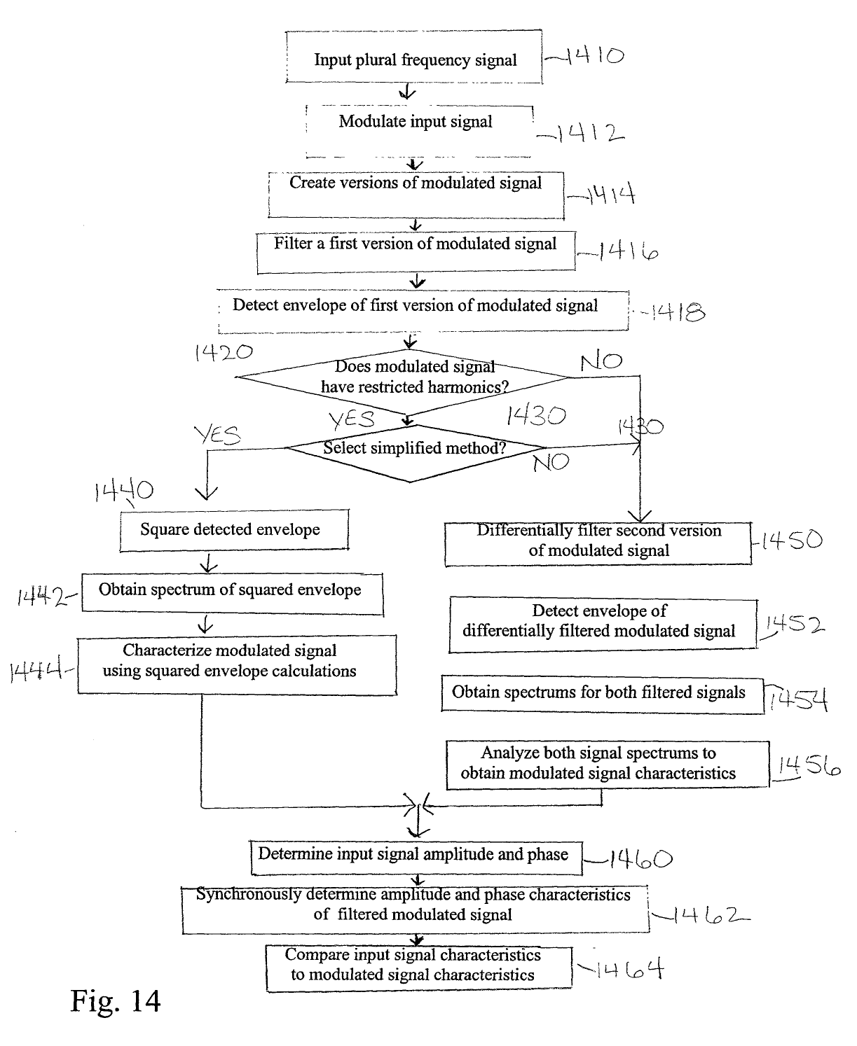

FIG. 14 shows a general method for determining characteristics of a modulated signal, irrespective of the modulation. Steps are also shown for applying the method within a method for characterizing the input/output performance of a modulator, or a system or device including a modulator. The mathematical details of the calculations are as described previously, and are not detailed in FIG. 14. First method blocks 1410 and 1412 are steps which are part of the method for input/output characterization, but may be taken as given for characterizing the modulated signal. At block 1410, a signal is input which has a plurality of frequency components; these may be the positive and negative frequencies of a periodic signal with a single tone, or may include many such positive and negative frequencies. The plurality may also include two or more different single sideband tones. The input signals may have arbitrary phase and amplitude with respect to each other, or may be related as in the case of positive and negative frequencies of a single sinusoidal signal. The signal may have a single input, or two or more input lines. A typical example would include I and Q inputs. At block 1412 the input signal is modulated, typically at least in part by multiplying with a carrier signal.

At block 1414, a plurality of versions of the modulated signal are created. In the simplest case block 1414 may simply entail splitting the signal to form two substantially identical versions of the split signal. However, as long as the relationship between the two versions is known after the step of forming versions, the finished versions need not be identical. Moreover, there may be a multiplicity of such signals created at this block. This block is part of the general modulated signal characterization method, but is not necessary for the simplified modulated signal characterization method.

At block 1416, at least a first version of the modulated signal is filtered. This filtering may be simply a unity gain and phase filter, i.e. a straight connection. At block 1418 a step of detecting an envelope of the first version of the modulated signal is performed. Blocks 1416 and 1418 are part of the modulating device characterization method, and form the beginning of the simplified modulated signal characterization method.

Blocks 1420 and 1430 are the steps which determine the type of signal characterization to be performed, whether the general method or a simplified method. At block 1420, the condition of the harmonics of the modulated signal are considered; if they are substantially restricted to a reference frequency and frequencies differing from the reference frequency by odd harmonics of a delta frequency, then a simplified method is possible, and control is passed to block 1430. However, if the modulated signal does not have a restricted harmonic content, then the more general method should be used; thus control passes to a block 1450. Even if the modulated signal has restricted harmonic content (e.g. as shown in FIG. 9), at the block 1430 it may be decided not to use the simplified method. In this case, as well, control passes to the block 1450.

If both decisions of the blocks 1420 and 1430 are affirmative, then control passes to a block 1440. There, the detected envelope of the filtered version of the modulated signal is squared. Then, at step 1442, the phase and amplitude of frequency components of the squared envelope signal are obtained. This is generally done by digitizing the signal and performing a FFT. If the digitizing is done earlier, the envelope detection and squaring may both be performed digitally. The information measured (or calculated from measurements) by the block 1442 may then be calculated, according to the appropriate squared envelope mathematics described previously, to characterize the modulated signal. Thus, the steps of the block 1444 complete the simplified modulated signal characterization method which began at the block 1418 (but could also, of course, include further steps such as those of the blocks 1410-1416).

If the method continued into the block 1450 then the more general modulated signal characterization will be performed. The block 1450 indicates a step of differentially filtering at least a second version of the modulated signal. It is primarily important only that the filtering of the first version differ from the filtering of the second or other versions. The filtering is preferably an analog process completed before the signals are digitized. The steps in the block 1450 would typically be performed at the same time as the steps of the block 1416. Then at a block 1452, which may be performed at the same time as the steps of the block 1418, an envelope of this second differentially filtered version of the modulated signal is detected. This may be done sequentially with the envelope detection of the block 1418, for example in the case that the signal is digitized and stored before envelope detection is performed as a programmatic function. If the envelope detection is an analog process, then the steps of blocks 1418 and 1452 will generally be performed simultaneously.

At a block 1454 the spectrums of both filtered and envelope detected modulated signals are obtained. Using the mathematical methods described above for the differentially filtered modulated signal, at a block 1456 the measurement information determined in the block 1454 may be used to determine the amplitude and phase characteristics of the modulated signal. Thus, after the block 1456, the general method for characterizing the modulated signal which began at the block 1414 is completed.

However, to apply this method to characterizing a modulating device, the method should continue to a block 1460, where signal amplitude and phase of the input signal is obtained. This will generally be done based upon a trigger signal so that the steps of a block 1462 may be performed for synchronously determining the amplitude and phase characteristics of the modulated signal for phase-coherent comparison with the amplitude of the input signal. The comparison of the output to the input, which completes the characterization, is completed in a block 1464.

While the above detailed description has shown, described, and pointed out novel features of the invention as applied to various embodiments, the skilled person will be understood that various omissions, substitutions, and changes in the form and details of the device or process illustrated may be made without departing from the scope of the invention. Therefore, the scope of the invention is indicated by the appended claims rather than by the foregoing description. All changes which come within the meaning and range of equivalency of the claims are to be embraced within their scope.

What is claimed is:

1. A method of characterizing a response of an electronic device to an input signal, the method comprising:
inputting into the device a periodic signal including a plurality of frequency components, and receiving a corresponding modulated output from the device;
detecting an envelope of a filtered version of the modulated output;
creating an envelope detection output based upon the detected envelope;
determining spectral components of the envelope detection output; and
comparing the determined spectral components of the envelope detection output to spectral components of the input signal.

2. The method of claim 1, wherein the filtered version of the modulated output is not significantly different from the modulated output.

3. The method of claim 1, further comprising:
creating a first version and a second version of the modulated output as treated by a known transfer function;
filtering the first version of the modulated output with a known filter transfer function to produce a first filtered modulated output;
filtering the second version of the modulated output with a different second known filter transfer function to produce a different second filtered modulated output;
detecting a first envelope of the first filtered modulator output and a second envelope of the second filtered modulated output;
determining a first spectral content of the first envelope and a second spectral content of the second envelope;
combining the first spectral content and the second spectral content to form a combined output spectral content; and
comparing the combined output spectral content to the input spectral content.

4. The method of claim 1, wherein the step of inputting into the device further comprises inputting a multiple frequency signal such that, within an output measurement frequency range, the modulated output is substantially limited to a first frequency and frequencies differing from the first frequency by odd multiples of a delta frequency.

5. The method of claim 4, wherein the step of creating an envelope detection output further comprises squaring the result of the envelope detection.

6. The method of claim 4, wherein the step of inputting into the device comprises inputting both I and Q signals.

7. An apparatus for characterizing a response of a modulating device to an input signal, comprising:
a signal source configured to produce a periodic modulating device input signal having a plurality of frequency components;
an envelope detector configured to detect an envelope of a modulated signal derived from an output of the modulating device responsive to the input signal;
an envelope combiner having a combined envelope output;
a spectrum detector configured to determine a spectrum of the combined envelope output; and
a spectrum comparator configured to compare the spectrum of the combined envelope output with a spectrum of the modulating device input signal.

8. The apparatus of claim 7 wherein the envelope combiner is configured to combine an envelope with itself to form the combined envelope output.

9. The apparatus of claim 8 wherein the signal source is configured to provide a signal to the modulating device resulting in an output from the modulating device having spectral output within a spectral frequency range which is substantially limited to components including a first frequency and other frequencies differing from the first frequency by an odd multiple of a delta frequency.

10. The apparatus of claim 7, further comprising:
a signal duplicator configured to provide duplicate modulated signals each reflecting the modulated signal;
a plurality of different filters each configured to differently filter each of the duplicate modulated signals;
one or more envelope detectors configured to detect an envelope of each filtered modulated signal;
a spectral analyzer configured to determine an amplitude and phase of the envelope of each filtered modulated signal; and
a spectrum comparator to compare the amplitude and phase of the envelopes of each filtered modulated signal
wherein the envelope combiner is configured to.

11. A method of characterizing amplitude and phase of signals which have been modulated, comprising:
obtaining a modulated signal;
detecting an envelope of the modulated signal;
squaring the detected envelope to form a squared envelope signal;
determining amplitude and phase of components of the squared envelope signal; and
calculating amplitude and phase of components of the modulated signal from the amplitudes and phases of components of the squared envelope signal.

12. The method of claim 11 wherein the modulated signal is substantially restricted to spectral components having frequencies which vary from a reference frequency by odd harmonics of a delta frequency.

13. A method of characterizing a response of an electronic device to an input signal, the method comprising:
inputting into the device a periodic signal including a plurality of frequency components, and receiving a corresponding modulated signal from the device;
detecting an envelope of a filtered version of the modulated signal according to the method of claim 12; and
comparing the determined spectral components of the modulated signal to spectral components of the input signal.

14. Apparatus for characterizing a multisine signal which has been modulated to form a modulated multisine signal, comprising:
a splitter to form a first version and a second version of the modulated multisine signal;
a first filter configured to filter the first version of the modulated multisine signal;
a second filter configured to differently filter the second version of the modulated multisine signal;
an envelope detector to determine an envelope of the first version of the modulated multisine signal;
a second envelope detector to detect an envelope of the differently filtered second version of the modulated multisine signal;
a first spectrum analyzer to determine a spectrum of the first version of the modulated multisine signal;
a second spectrum analyzer to determine a spectrum of the differently filtered second version of the modulated multisine signal; and
a processor configured to calculate phase and amplitude of the modulated multisine signal from the spectrums of the differently filtered first and second versions of the modulated multisine signals.

15. The apparatus of claim 14 further including a digitizer.

16. The apparatus of claim 15, wherein the first and second envelope detectors are both part of a single digital envelope detection module.

17. The apparatus of claim 16 wherein the digital envelope detection module operates on first and second data streams, the first data stream is a digitized output from the first filter, and the second data stream is a digitized output from the second filter.

18. The apparatus of claim 14 wherein one of the filters has substantially unity gain and phase characteristics.

19. The apparatus of claim 14 wherein the splitter outputs substantially identical versions of the modulated multisine signal.

20. A system for determining the characteristics of a modulating device transfer function with respect to an input modulation signal, the system comprising:
a signal source module configured to provide the input modulation signal having a plurality of frequency components;
a modulating device to be characterized, the modulating device accepting the input modulation signal;
the apparatus of claim 14 configured to characterize an output from the modulating device;
a spectrum analyzer configured to measure a spectrum of the input signal synchronously with the spectral measurement of the modulated multisine signal; and
a processor to compare the phase and amplitude of the modulated multisine signal with phase and amplitude of the input modulation signal.

21. A system for determining the characteristics of a modulating device transfer function with respect to an input modulation signal, the system comprising:
a signal source module configured to provide the input modulation signal having a plurality of frequency components;
a modulating device to be characterized, the modulating device accepting the input modulation signal;
the apparatus of claim 16 configured to characterize an output from the modulating device;
a spectrum analyzer configured to measure a spectrum of the input signal synchronously with the spectral measurement of the modulated multisine signal; and
a processor to compare the phase and amplitude of the modulated multisine signal with phase and amplitude of the input modulation signal.

22. A system for determining the characteristics of a modulating device transfer function with respect to an input modulation signal, the system comprising:
a signal source module configured to provide the input modulation signal having a plurality of frequency components;
a modulating device to be characterized, the modulating device accepting the input modulation signal;
the apparatus of claim 18 configured to characterize an output from the modulating device;
a spectrum analyzer configured to measure a spectrum of the input signal synchronously with the spectral measurement of the modulated multisine signal; and
a processor to compare the phase and amplitude of the modulated multisine signal with phase and amplitude of the input modulation signal.

23. A system for determining the characteristics of a modulating device transfer function with respect to an input modulation signal, the system comprising:
a signal source module configured to provide the input modulation signal having a plurality of frequency components;
a modulating device to be characterized, the modulating device accepting the input modulation signal;
the apparatus of claim 19 configured to characterize an output from the modulating device;
a spectrum analyzer configured to measure a spectrum of the input signal synchronously with the spectral measurement of the modulated multisine signal; and
a processor to compare the phase and amplitude of the modulated multisine signal with phase and amplitude of the input modulation signal.
